(19) United States
(12) Patent Application Publication
(10) Pub. No.: US 2018/0076408 A1
(43) Pub. Date: Mar. 15, 2018

(54) LIGHT EMITTING DEVICE

(71) Applicant: PIONEER CORPORATION, Bunkyo-ku, Tokyo (JP)

(72) Inventor: Takahito OYAMADA, Kawasaki-shi (JP)

(21) Appl. No.: 15/560,442

(22) PCT Filed: Mar. 24, 2015
(86) PCT No.: PCT/JP2015/058966

§ 371 Date: Sep. 21, 2017

(51) Int. Cl. H01L 51/50; H05B 33/10; H05B 33/22; H05B 33/26; H05B 33/14; H01L 51/52

(52) U.S. Cl. CPC H01L 51/5036; H05B 33/10; H05B 33/22; H05B 33/26; H01L 51/0085; H01L 51/5234; H01L 2251/5376; H01L 2251/558; H05B 33/14

(57) ABSTRACT

A light emitting unit (140) includes a first light emitting region (140a) and a second light emitting region (140b). The first light emitting region (140a) and the second light emitting region (140b) are adjacent each other, each region including a first electrode, an organic layer, and a second electrode. The organic layer is located between the first electrode and the second electrode. A light limiting layer (154) is formed between the first light emitting region (140a) and the second light emitting region (140b). The light limiting layer (154) prevents light incident on the second light emitting region (140b) from being incident on the first light emitting region (140a).

### TECHNICAL FIELD

The present invention relates to a light emitting device.

### BACKGROUND ART

In recent years, there has been advancement in the development of light emitting devices including an organic electroluminescence (EL) element as a light emitting element. The organic EL element is configured of an organic layer interposed between a first electrode and a second electrode. Examples of the light emitting device with the organic EL element include an illumination device, a display device, and the like.

There is sometimes a demand for the light emitting device having the same organic layers in a light emitting region to have a light emission color in a portion of the light emitting region that is different from a light emission color in another portion of the light emitting region. In response to such a demand, Patent Document 1 discloses denaturing (deteriorating) an organic pigment in a portion of a light emitting region to differentiate the light emission color in that portion from a light emission color in another portion of the light emitting region. Patent Document 1 discloses a method of performing irradiation with electromagnetic waves, for example, i rays of a high pressure mercury lamp, as a method of denaturing (deteriorating) an organic pigment.

Meanwhile, Patent Document 2 discloses that an initial reduction in luminescence may be suppressed by irradiating a hole transfer layer with light from a side opposite to a substrate after forming a hole injection layer and the hole transfer layer and before forming a light emitting layer.

### RELATED DOCUMENT

### Patent Document

[Patent Document 1] International Publication No. WO1997/43874

[Patent Document 2] Japanese Laid-open Patent Publication No. 2011-210613

### SUMMARY OF THE INVENTION

### Technical Problem

Patent Document 1 discloses a method of deteriorating an organic pigment of a portion of a light emitting region to thereby make the light emission color in the portion of the light emitting region different from the light emission color in another portion of the light emitting region. However, since the method allows the organic pigment in the light emitting layer to be deteriorated, there is a risk that the life span of the light emitting device may be reduced.

An exemplary object of the invention is to make a light emission color in a portion of a light emitting region different from a light emission color in another portion of the light emitting region without reducing the life span of a light emitting device.

### Solution to Problem

According to a first aspect of the invention, there is provided a light emitting device including

a substrate and

a light emitting unit on the substrate,

in which the light emitting unit includes a first light emitting region and a second light emitting region, and

in which the first light emitting region and the second light emitting region are adjacent each other, each of the first light emitting region and the second light emitting region including a first electrode, a second electrode, and an organic layer between the first electrode and the second electrode,

the light emitting device further including

a light limiting layer on the substrate between the first light emitting region and the second light emitting region, the light emitting layer preventing light incident on the second light emitting region from being incident on the first light emitting region.

According to a second aspect of the invention, there is provided a light emitting device including

a substrate,

a first light emitting region and a second light emitting region adjacent each other on the substrate, and

a light limiting layer on the substrate between the first light emitting region and the second light emitting region,

in which the light limiting layer includes a low transmittance material having a light transmittance lower than a light transmittance of a material constituting the light limiting layer.

### BRIEF DESCRIPTION OF THE DRAWINGS

The above-described object, other objects, features and advantages will be further apparent from the preferred embodiments described below, and the accompanying drawings as follows.

FIG. 1 is a plan view illustrating a configuration of a light emitting device according to an exemplary embodiment.

FIG. 2 is a diagram in which a second electrode is removed from FIG. 1.

FIG. 3 is a diagram in which an insulating layer and an organic layer are removed from FIG. 2.

FIG. 4 is a cross-sectional view taken along line A-A of FIG. 1.

FIG. 5 is a cross-sectional view illustrating a configuration of an organic layer.

FIG. 6 is a cross-sectional view illustrating a method of manufacturing a light emitting device.

FIG. 7 is a diagram illustrating an example of a light emission spectrum in a first light emitting region and a light emission spectrum in a second light emitting region.

FIG. 8 is a diagram in which the light emission spectrum illustrated in FIG. 7 is normalized at a first peak.

FIG. 9 is a diagram illustrating how the light emission spectrum of the first light emitting region changes depending on the magnitude of a current.

FIG. 10 is a diagram in which the light emission spectrum illustrated in FIG. 9 is normalized at a first peak.

FIG. 11 is a diagram illustrating how the light emission spectrum of the second light emitting region changes depending on the magnitude of a current.

FIG. 12 is a diagram in which the light emission spectrum illustrated in FIG. 11 is normalized at a first peak.

FIG. 13 is a diagram illustrating a view of the light emitting device including a light emitting unit having a first current flowing thereto seen from a second surface side of a substrate.

FIG. 14 is a diagram illustrating a view of the light emitting device including the light emitting unit having a second current flowing thereto seen from the second surface side of the substrate.

FIG. 15 is a plan view illustrating a configuration of a light emitting device according to Modification Example 1.

FIG. 16 is a diagram in which a second electrode is removed from FIG. 15.

FIG. 17 is a diagram in which an insulating layer and an organic layer are removed from FIG. 16.

FIG. 18 is a plan view illustrating a configuration of a light emitting device according to Modification Example 2.

FIG. 19 is a diagram in which an insulating layer and an organic layer are removed from FIG. 18.

FIG. 20 is a cross-sectional view taken along line B-B of FIG. 18.

FIG. 21 is a diagram illustrating a modification example of FIG. 20.

FIG. 22 is a cross-sectional view illustrating a configuration of a light emitting device according to Modification Example 3.

### DESCRIPTION OF EMBODIMENTS

Hereinafter, embodiments of the invention will be described with reference to the accompanying drawings. In all the drawings, like reference numerals denote like components, and a description thereof will not be repeated.

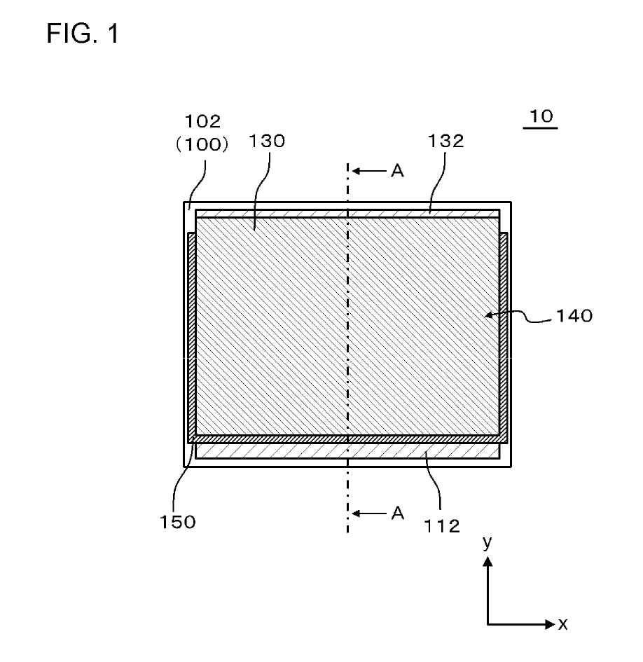

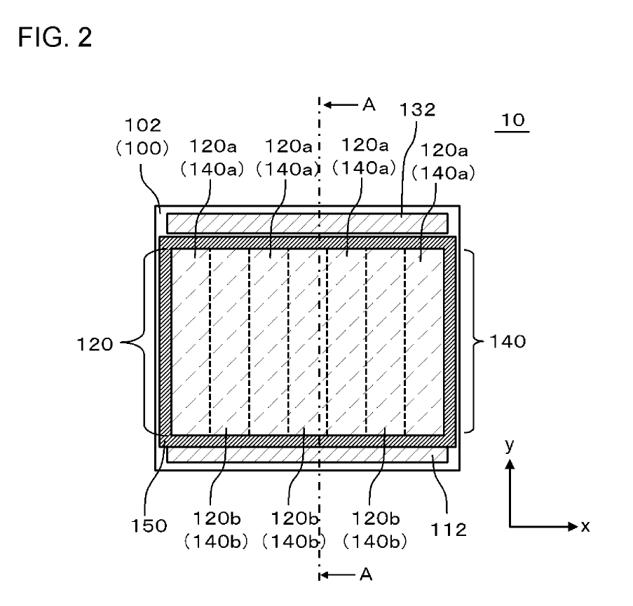

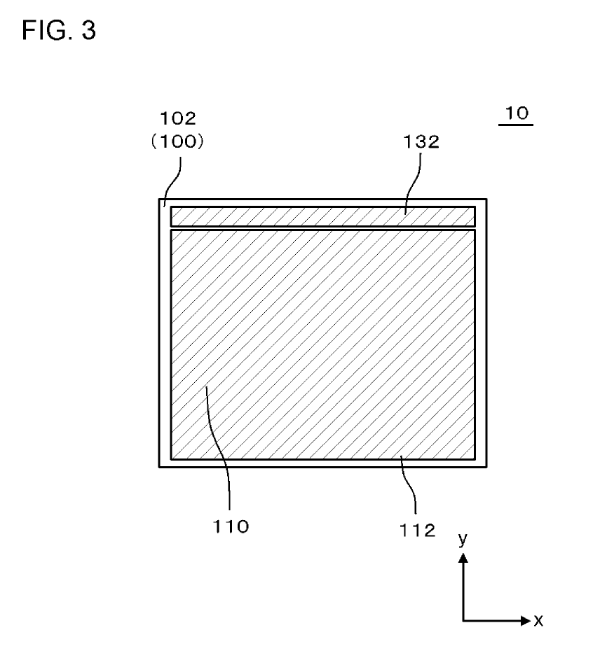

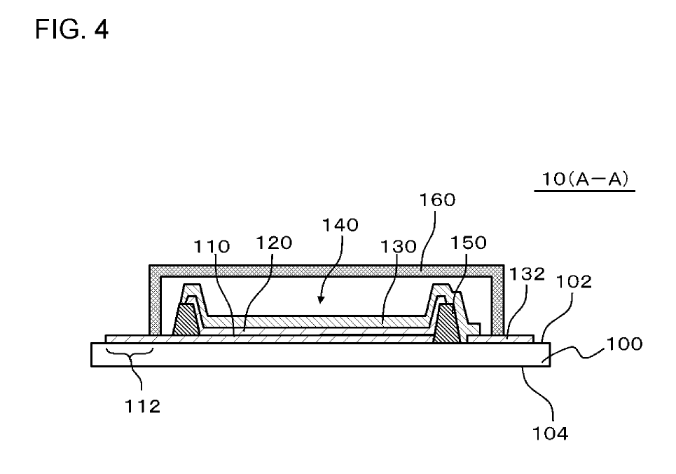

FIG. 1 is a plan view illustrating a configuration of a light emitting device 10 according to an exemplary embodiment. FIG. 2 is a diagram in which a second electrode 130 is removed from FIG. 1. FIG. 3 is a diagram in which an insulating layer 150 and an organic layer 120 are removed from FIG. 2. FIG. 4 is a cross-sectional view taken along line A-A of FIG. 1. Meanwhile, for convenience of description, a sealing portion 160 is not shown in FIG. 1.

The light emitting device 10 according to the present exemplary embodiment includes a substrate 100 and a light emitting unit 140. The light emitting unit 140 is formed on the substrate 100 and includes a first light emitting region 140a and a second light emitting region 140b, as illustrated in FIG. 2. The first light emitting region 140a and the second light emitting region 140b are adjacent each other, each of the regions 140a and 140b including a first electrode 110, an organic layer 120, and a second electrode 130. The organic layer 120 is located between the first electrode 110 and the second electrode 130. Each of a light emission spectrum in the first light emitting region 140a (hereinafter, referred to as a first light emission spectrum) and a light emission spectrum in the second light emitting region 140b (hereinafter, referred to as a second light emission spectrum) has a first peak and a second peak. A peak wavelength of the first peak of the first light emission spectrum and a peak wavelength of the first peak of the second light emission spectrum are the same as each other. Similarly, a peak wavelength of the second peak of the first light emission spectrum and a peak wavelength of the second peak of the second light emission spectrum are the same as each other. An intensity ratio (hereinafter, referred to as a peak intensity ratio) of the second peak to the first peak in the first light emitting region 140a is different from an intensity ratio in the second light emitting region 140b. Hereinafter, the light emitting device 10 will be described in detail.

The substrate 100 is formed of a material, such as glass or a transmissive resin, which transmits visible light. However, in a case where the light emitting device 10 is a top-emission type, the substrate 100 may be formed of a non-transmissive material. The substrate 100 is a polygon such as a rectangle. The substrate 100 maybe flexible. In a case where the substrate 100 is flexible, the thickness of the substrate 100 is, for example, equal to or greater than 10 μm and equal to or less than 1,000 μm. In particular, in a case where the substrate 100 is glass, the thickness of the substrate 100 is, for example, equal to or less than 200 μm. In a case where the substrate 100 is a resin, the substrate 100 is formed of, for example, polyethylene naphthalate (PEN), polyethersulfone (PES), polyethylene terephthalate (PET), or polyimide. When the substrate 100 is a resin, the substrate 100 allows moisture to easily pass therethrough. In order to suppress transmission of moisture, an inorganic barrier film such as SiNₓ or SiON is formed on at least a light emission surface side (preferably, both surfaces) of the substrate 100.

The light emitting unit 140 includes an organic EL element. The organic EL element is configured by laminating the first electrode 110, the organic layer 120, and the second electrode 130 on a first surface 102 of the substrate 100 in this order.

The first electrode 110 is a transparent electrode that transmits visible light. A transparent conductive material constituting the transparent electrode contains a metal, and is for example, a metal oxide such as indium tin oxide (ITO), indium zinc oxide (IZO), indium tungsten zinc oxide (IWZO), or zinc oxide (ZnO). The thickness of the first electrode 110 is, for example, equal to or greater than 10 nm and equal to or less than 500 nm. The first electrode 110 is formed by, for example, sputtering or vapor deposition. Meanwhile, the first electrode 110 may be an organic conductive material such as carbon nanotubes or PEDOT/PSS.

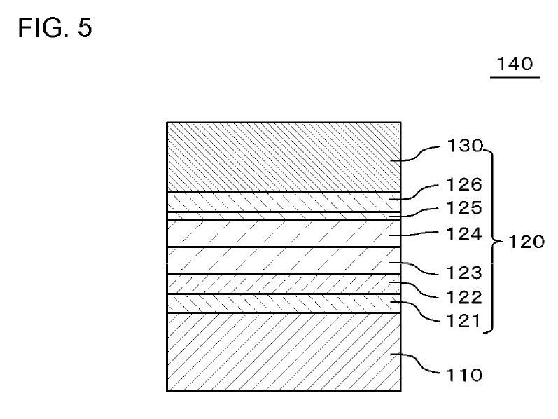

The organic layer 120 includes a light emitting layer. The organic layer 120 is configured by laminating, for example, a hole injection layer, a light emitting layer, and an electron injection layer. In the present exemplary embodiment, the organic layer 120 includes plural light emitting layers. Details of the configuration of the organic layer 120 will be described later with reference to FIG. 5.

For example, the second electrode 130 includes a metal layer constituted of a metal selected from a first group consisting of Al, Au, Ag, Pt, Mg, Sn, Zn, and In or an alloy of metals selected from the first group. The thickness of the second electrode 130 is, for example, equal to or greater than 10 nm and equal to or less than 500 nm. However, the second electrode 130 may be formed using the material exemplified as a material of the first electrode 110. The second electrode 130 is formed by, for example, sputtering or vapor deposition.

Meanwhile, the materials of the foregoing first electrode 110 and second electrode 130 are examples for when transmitting light through the substrate 100, that is, for performing light emission from the light emitting device 10 through the substrate 100 (bottom-emission light emitting device). As a different case, light may be transmitted through a side opposite to the substrate 100. That is, light emission from the light emitting device 10 is performed without passing through the substrate 100 (top-emission light emitting device). The laminating structure in the top emission light emitting device has one of an inverted layer sequence and a standard layer sequence. In the inverted layer sequence, the material of the first electrode 110 and the material of the second electrode 130 are reversed to those of the bottom emission light emitting device. That is, the foregoing material of the second electrode 130 is used as the material of the first electrode 110 and the foregoing material of the first electrode 110 is used as the material of the second electrode 130. In contrast, in the standard layer sequence, the material of the first electrode 110 is formed on the foregoing material of the second electrode 130, the organic layer 120 is formed on the first electrode 110, and the second electrode 130, made into a thin film, is further formed on the organic layer 120, thus achieving a structure for taking out light from the side of the device opposite to the substrate 100. The light emitting device 10 according to the present exemplary embodiment may have any type of structure among the bottom emission light emitting device and the foregoing two types of top emission light emitting devices.

In addition, the light emitting device 10 includes a first terminal 112 and a second terminal 132. The first terminal 112 is electrically connected to the first electrode 110. For example, the first terminal 112 includes a layer formed of the same material as that of the first electrode 110. Further, this layer may be formed integrally with the first electrode 110. In addition, the second terminal 132 is electrically connected to the second electrode 130. In addition, the second terminal 132 also includes a layer formed of the same material as that of the first electrode 110. However, this layer is separated from the first electrode 110.

Meanwhile, an extraction interconnect may be provided between the first terminal 112 and the first electrode 110. In addition, an extraction interconnect may also be provided between the second terminal 132 and the second electrode 130.

In addition, a conductive layer formed of a material having a resistance lower than that of the first electrode 110 may be formed on the first electrode 110, on the first terminal 112, and on the second terminal 132. The conductive layer is formed of, for example, a metal or an alloy. The conductive layer may have a single-layered structure or a multi-layered structure. The conductive layer is configured by forming, for example, a Mo alloy layer (for example, a MoNb layer), an Al alloy layer (for example, an AlNd layer), and a Mo alloy layer (for example, a MoNb layer) in this order. A portion of the conductive layer located on the first electrode 110 is formed as, for example, plural linear electrodes. In addition, a portion of the conductive layer located on the first terminal 112 maybe formed on the entire surface of the first terminal 112. Further, a portion of the conductive layer located on the second terminal 132 may be formed on the entire surface of the second terminal 132. The formation of the conductive layer enables to decrease the apparent resistances of the first electrode 110, the first terminal 112, and the second terminal 132.

In addition, the light emitting device 10 includes an insulating layer 150. The insulating layer 150 is provided on the first surface 102 of the substrate 100 in order to define the light emitting unit 140. In the example illustrated in FIG. 2, the insulating layer 150 covers the edge of the first electrode 110. The insulating layer 150 is formed of a polyimide, epoxy, acrylic or novolac-based resin material. For example, the insulating layer 150 is formed by mixing a photosensitive material in a resin material to be the insulating layer 150, and applying and then exposing and developing the mixed resin material. In addition, the insulating layer 150 maybe formed by inkjet printing or screen printing.

In the organic layer 120, an organic layer 120a is located in a region serving as the first light emitting region 140a, and an organic layer 120b is located in a region serving as the second light emitting region 140b. When the current density is a fixed value or less, the light emission color (color temperature) of the organic layer 120a is different from the light emission color (color temperature) of the organic layer 120b. However, as described later, as the current density increases, the difference between the color temperatures of the organic layer 120a and the organic layer 120b decreases, until finally there is hardly any difference therebetween.

The organic layers 120a and 120b have the same layered structure and are formed by the same process using the same material. For this reason, it is difficult to distinguish between the organic layer 120a and the organic layer 120b when the light emitting device 10 is not emitting light.

In addition, as illustrated in FIGS. 1 and 3, the light emitting unit 140 includes one first electrode 110 and one second electrode 130. Therefore, the first electrode 110 in the first light emitting region 140a is electrically and physically connected to the first electrode 110 in the second light emitting region 140b. In addition, the second electrode 130 in the first light emitting region 140a is electrically and physically connected to the second electrode 130 in the second light emitting region 140b.

As illustrated in FIG. 4, the light emitting device 10 includes a sealing portion 160. The sealing portion 160 seals the light emitting unit 140. The sealing portion 160 illustrated in the drawing is a sealing member and is formed using a metal, such as glass or aluminum, or a resin. The sealing portion 160 is a polygon or a circle similar to the substrate 100 and is provided with a concave portion in the center thereof. The edge of the sealing portion 160 is fixed to the substrate 100 by an adhesive. Thereby, a space surrounded by the sealing portion 160 and the substrate 100 is sealed. The light emitting unit 140 is located in the sealed space.

Meanwhile, the sealing member may be a film formed by atomic layer deposition (ALD) or chemical vapor deposition (CVD). The thickness of the sealing film is, for example, equal to or greater than 10 nm and equal to or less than 1,000 nm. In a case where the sealing film is formed by ALD, the sealing film may have, for example, at least one of an aluminum oxide film and a titanium oxide film or a laminated film of these materials. In a case where the sealing film is formed by CVD or sputtering, the sealing film is formed of an insulating film such as SiO₂ or SiN.

FIG. 5 is a cross-sectional view illustrating a configuration of the organic layer 120. The organic layer 120 includes a second light emitting layer 123 and a first light emitting layer 124 between a hole injection layer 121 and an electron injection layer 126 (or an electron transport layer). In detail, the organic layer 120 is configured by laminating the hole injection layer 121, the hole transfer layer 122, the second light emitting layer 123, the first light emitting layer 124, the hole blocking layer 125, and the electron injection layer 126 over the first electrode 110 in this order. The hole injection layer 121 is in contact with the first electrode 110, and the electron injection layer 126 is in contact with the second electrode 130. An internal light emission spectrum of the second light emitting layer 123 has a second peak, and an internal light emission spectrum of the first light emitting layer 124 has a first peak. Therefore, a first peak of a light emission spectrum of the output of the light emitting unit 140 (hereinafter, referred to as a light emission output spectrum) is derived from the internal light emission spectrum of the first light emitting layer 124, and a second peak of the light emission output spectrum of the light emitting unit 140 is derived from the internal light emission spectrum of the second light emitting layer 123. The first peak is positioned in, for example, a blue wavelength region, and the second peak is positioned in, for example, a red wavelength region. In addition, plural light emission peaks may be derived from a single layer of the first light emitting layer 124 or the second light emitting layer 123. For example, peaks in a red wavelength region and a green wavelength region may derive from the second light emitting layer 123. Meanwhile, at least one of the hole transfer layer 122 and the hole blocking layer 125 may not be provided.

Meanwhile, for example, the light emission output spectrum is shown by a result obtained by measuring the light emission of the lighted light emitting unit 140 from the outside thereof by a spectrophotometer. In addition, for example, the internal light emission spectrum is shown by a result obtained by measuring photoluminescence of a light emitting layer to be measured, by a micro photoluminescence measurement device. When a comparison is made between a light emission output spectrum in the first light emitting region 140a with a light emission output spectrum in the second light emitting region 140b measured in the above manner, the peak wavelengths thereof are in common with each other, but the peak intensity ratios thereof are different from each other. On the other hand, when a comparison is made between an internal light emission spectrum in the first light emitting region 140a with an internal light emission spectrum in the second light emitting region 140b, both the peak wave lengths and the peak intensity ratios are in common with each other (substantially the same).

Each of layers constituting the organic layer 120 may be formed by vapor deposition. In addition, at least one layer in the organic layer 120, for example, the hole injection layer 121 that is in contact with the first electrode 110 may be formed by inkjet printing, printing, or coating such as spraying. Meanwhile, in this case, the remaining layers of the organic layer 120 may be formed by vapor deposition. Alternatively, all of the layers of the organic layer 120 may be formed by coating. In addition, in a case where the second light emitting layer 123 is formed by coating, the first light emitting layer 124 may be formed by vapor deposition. Meanwhile, either a fluorescent material or a phosphorescent material may be used for the first light emitting layer 124 and the second light emitting layer 123. However, the phosphorescent material is preferably used from the viewpoint of an improvement in internal quantum efficiency. In this case, examples of the phosphorescent material to be used include a phosphorescent organometallic complex and the like containing one or two or more kinds of heavy atoms having an atomic weight of equal to or greater than 100 and equal to or less than 200, selected from iridium, platinum, osmium, rhenium, gold, tungsten, ruthenium, hafnium, europium, terbium, rhodium, palladium, silver and the like.

Next, a method of manufacturing the light emitting device 10 will be described. First, the first electrode 110 is formed on the first surface 102 of the substrate 100. In this process, the first terminal 112 and the second terminal 132 are also formed. Subsequently, a resin material to be the insulating layer 150 is coated onto the first surface 102 of the substrate 100 and then exposed and developed. Thereby, the insulating layer 150 is formed.

Subsequently, the organic layer 120 is formed in a region of the first electrode 110 surrounded by the first insulating layer 150. Subsequently, the second electrode 130 is formed. Thereafter, the sealing portion 160 is provided.

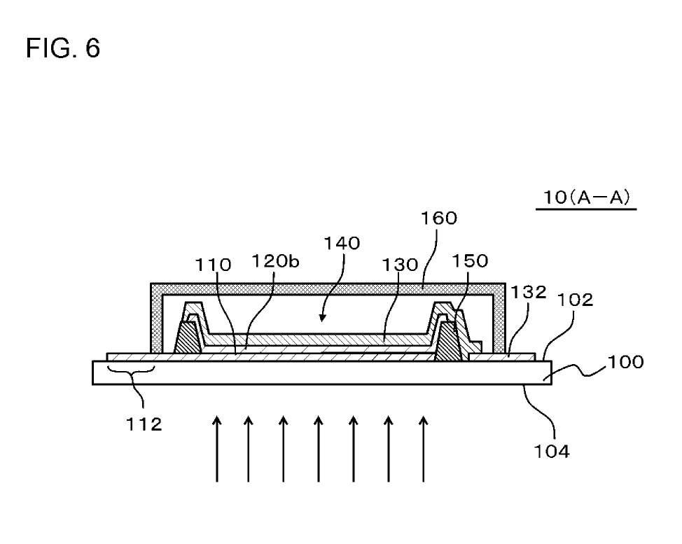

Subsequently, as illustrated in FIG. 6, a portion of the organic layer 120 located in a region to be the first light emitting region 140a is irradiated with light for heating the organic layer 120, the light irradiated from the second surface 104 side of the substrate 100 through the substrate 100 and the first electrode 110. The light includes, for example, light in a near-infrared region or an infrared region. In addition, the intensity of the light is, for example, equal to or greater than 1 W and equal to or less than 10,000 W, with the irradiation time of, for example, equal to or greater than one second and equal to or less than 36,000 seconds, thereby heating the portion of the organic layer 120 located in the region to be the first light emitting region 140a. As a result, the peak intensity ratio (that is, “intensity of second peak”/“intensity of first peak”) of a light emission output spectrum of a portion of the organic layer 120 located in the first light emitting region 140a (organic layer 120a) is different from the peak intensity ratio of a light emission output spectrum of a portion of the organic layer 120 not irradiated with light, that is, a portion located in the second light emitting region 140b (organic layer 120b).

Meanwhile, the reason for the difference between the peak intensity ratios of the organic layer 120a and the organic layer 120b is considered to be due to the carrier balance of at least one of the second light emitting layer 123 and the first light emitting layer 124 changing by the organic layer 120 being irradiated with light, and a portion (binding site) having the largest binding amount between holes and electrons moving. In addition, in a case where the light emitting device 10 is the above-described top-emission light emitting device, it is possible to irradiate the organic layer 120 with the above-mentioned light for heating from the sealing portion 160 side (side of the first surface 102 of the substrate 100) by selecting a transmissive material for the sealing portion 160.

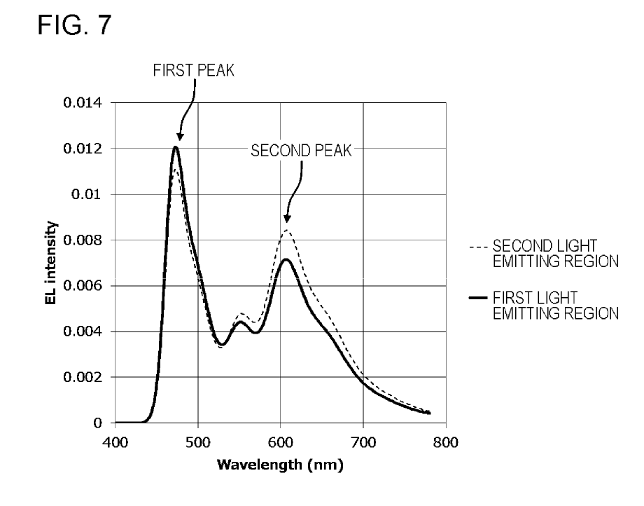

FIG. 7 is a diagram illustrating examples of a light emission output spectrum in the first light emitting region 140a and a light emission output spectrum in the second light emitting region 140b. In the example illustrated in the drawing, the two light emission output spectrums have plural peaks, and the positions of the respective plural peaks, that is, the peak wavelengths thereof, are the same as each other. The first peaks are positioned in a blue wavelength region, and the second peaks are positioned toward a longer wavelength side than the first peaks, specifically, in a red wavelength region. Meanwhile, in the example illustrated in the drawing, the two light emission output spectrums have a third peak in a green wavelength region. Thereby, the light emission color in the first light emitting region 140a and the light emission color in the second light emitting region 140b are white. Meanwhile, the light emission color changes to blue-tinged white (that is, higher color temperature) as the first peak becomes more intensified, and changes to red-tinged white (that is, lower color temperature) as the second peak becomes more intensified.

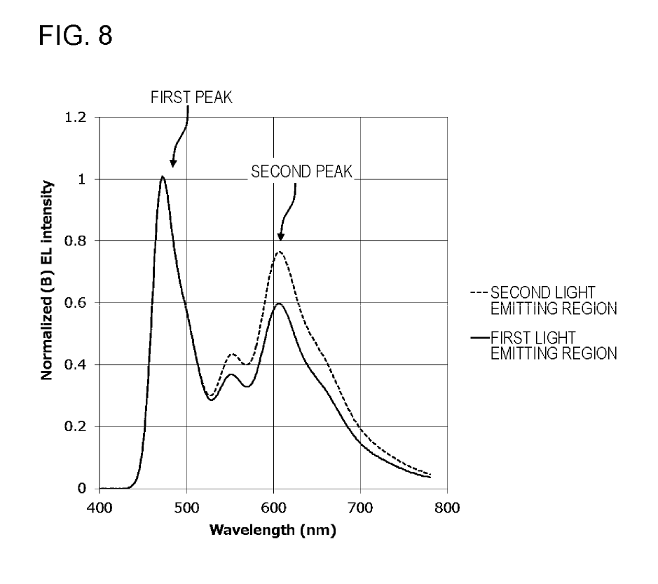

FIG. 8 is a diagram in which the light emission output spectrum illustrated in FIG. 7 is normalized at the first peak. The height of the second peak illustrated in the drawing indicates the above-mentioned peak intensity ratio (second peak/first peak). From the drawing, it can be understood that the peak intensity ratio in the first light emitting region 140a is different from the peak intensity ratio in the second light emitting region 140b. In the example illustrated in the drawing, the peak intensity ratio in the second light emitting region 140b is higher than the peak intensity ratio in the first light emitting region 140a. This means that the color temperature in the second light emitting region 140b is lower than the color temperature in the first light emitting region 140a.

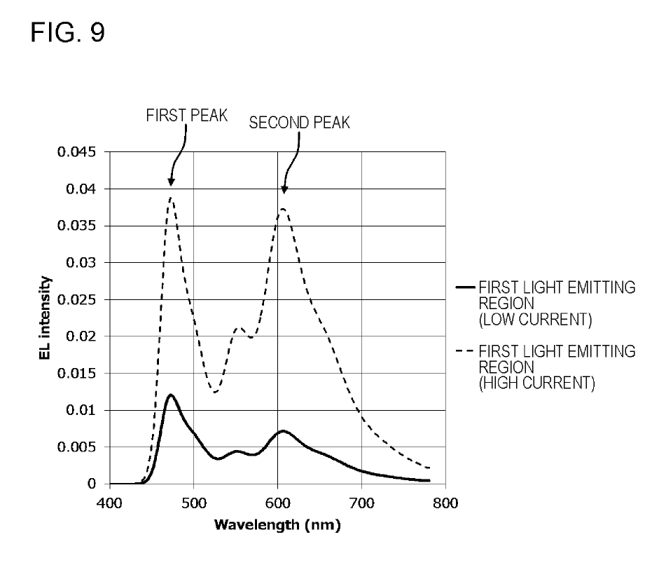

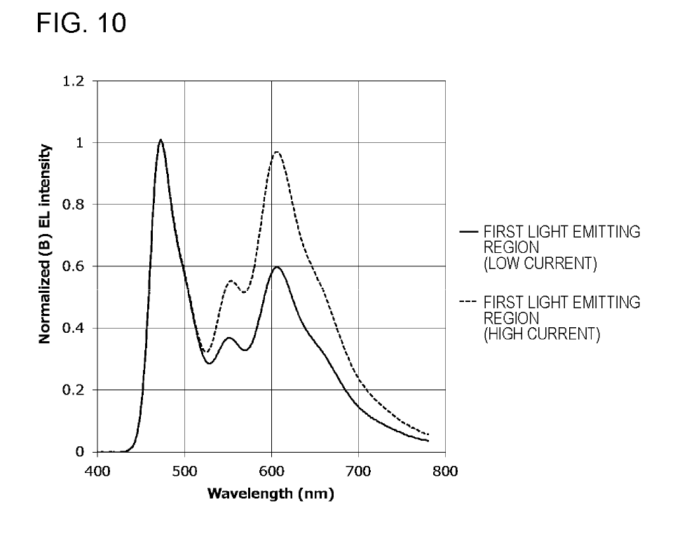

FIG. 9 is a diagram illustrating how the light emission output spectrum in the first light emitting region 140a changes depending on the magnitude of a current (current density). FIG. 10 is a diagram in which the light emission output spectrum illustrated in FIG. 9 is normalized at the first peak. The height of the second peak in FIG. 10 indicates the above-mentioned peak intensity ratio. In the first light emitting region 140a (that is, a region in FIG. 6 irradiated with light), light becomes more intensified as the current density increases, as illustrated in FIG. 9. As illustrated in FIG. 10, in the first light emitting region 140a, the first peak is higher than the second peak when a first current (for example, a current density of equal to or less than 5 mA/cm²) flows. In addition, when a second current (for example, a current density of equal to or greater than 6 mA/cm²) higher than the first current flows, the first peak is still higher than the second peak. However, as illustrated in FIG. 10, there is less difference between the first peak and the second peak when applying the second current. For this reason, the peak intensity ratio when applying the first current is different from the peak intensity ratio when applying the second current. Meanwhile, the current density of the second current is, for example, equal to or greater than 101% of the current density of the first current.

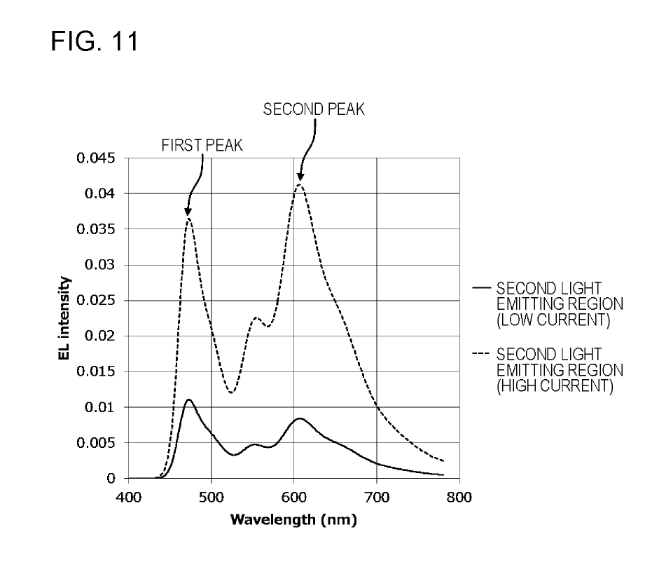

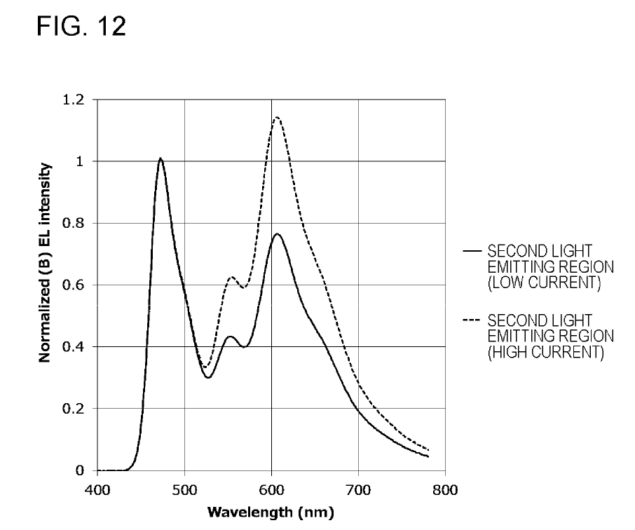

FIG. 11 is a diagram illustrating how the light emission output spectrum in the second light emitting region 140b changes depending on the magnitude of a current (current density). FIG. 12 is a diagram in which the light emission output spectrum illustrated in FIG. 11 is normalized at the first peak. The height of the second peak in FIG. 12 indicates the above-mentioned peak intensity ratio. As illustrated in FIG. 11, in the second light emitting region 140b (that is, a region not irradiated with light), the light emission intensity increases as the current increases. As illustrated in FIG. 12, in the first light emitting region 140a (that is, a region irradiated with light), when a first current (in the example illustrated in the drawing, a current density of 2.5 mA/cm²) flows, the first peak is higher than the second peak. On the other hand, when a second current flows with increased current density (in the example illustrated in the drawing, a current density of 10 mA/cm²), the first peak becomes lower than the second peak.

Meanwhile, when comparing FIG. 10 and FIG. 12, it can be understood that the difference between the peak intensity ratio in the first light emitting region 140a and the peak intensity ratio in the second light emitting region 140b when applying the first current is lower than the difference between the peak intensity ratio in the first light emitting region 140a and the peak intensity ratio in the second light emitting region 140b when applying the second current. This shows that the light emission color in the first light emitting region 140a and the light emission color in the second light emitting region 140b are different from each other when a current density is low, but the difference becomes smaller as the current density increases.

Meanwhile, when the entirety of the light emitting unit 140 is the first light emitting region 140a, the light emission output spectrum of the light emitting unit 140 indicates the properties illustrated in FIGS. 9 and 10.

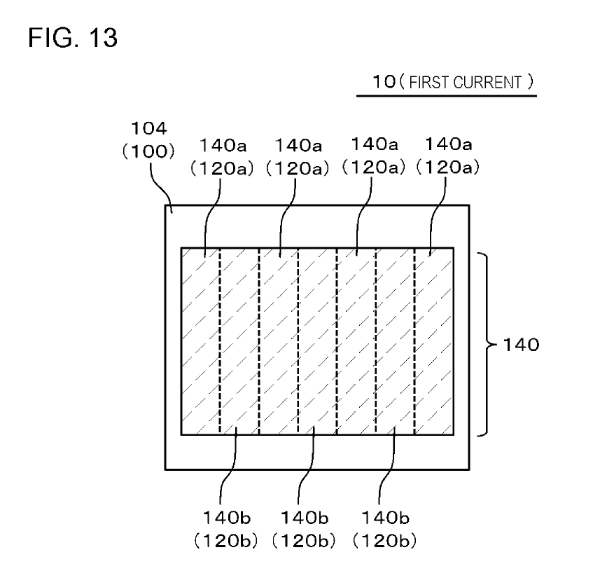

FIG. 13 is a diagram illustrating a view of the light emitting device 10 with the first current flowing into the light emitting unit 140 seen from the second surface 104 side (surface on a side opposite to the light emitting unit 140) of the substrate 100. The peak intensity ratio in the first light emitting region 140a in this state is different from the peak intensity ratio in the second light emitting region 140b. The light emission color in the first light emitting region 140a is therefore different from the light emission color in the second light emitting region 140b. Accordingly, a person is able to distinguish between the first light emitting region 140a and the second light emitting region 140b. Meanwhile, in FIG. 13, the first light emitting region 140a and the second light emitting region 140b are formed in stripes, but the shapes of the light emitting regions are appropriately selected and may be, for example, characters, signs, pictures, or a combination thereof.

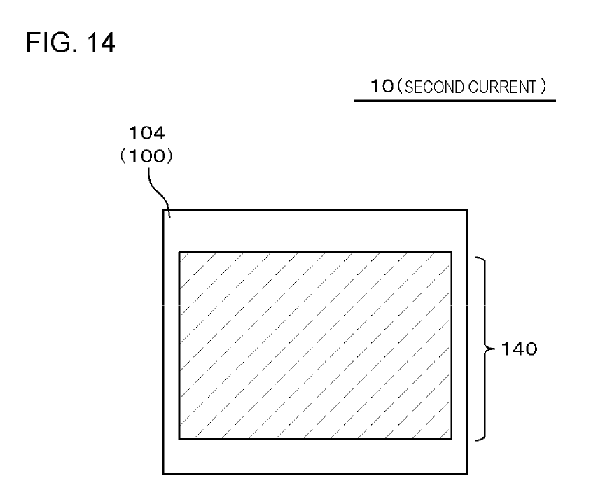

FIG. 14 is a diagram illustrating a view of the light emitting device 10 with the second current flowing into the light emitting unit 140 seen from the second surface 104 side of the substrate 100. The difference between the peak intensity ratio in the first light emitting region 140a and the peak intensity ratio in the second light emitting region 140b in this state is smaller than that in a case where the first current is applied. For this reason, the difference between the light emission color in the first light emitting region 140a and the light emission color in the second light emitting region 140b is smaller than that in the case illustrated in FIG. 13, and the colors become substantially the same as each other depending on conditions. Therefore, a person cannot distinguish between the first light emitting region 140a and the second light emitting region 140b and recognizes the light emitting unit 140 as one light emitting region.

In this manner, according to the light emitting device 10 in the present exemplary embodiment, it is possible to make a region equivalent to the first light emitting region 140a appear or disappear in the light emitting unit 140 by changing the current density. Meanwhile, characters, signs, or pictures may be used for a display of the first light emitting region 140a and a display that can be expressed by a difference in the light emission colors between the first light emitting region 140a and the second light emitting region 140b. The shape of the first light emitting region 140a is freely set by adjusting a region of the light emitting unit 140 irradiated with light. In this manner, it is possible to provide, using the level difference in current values, an OFF mode, a display mode for displaying using the difference in light emission colors between the first light emitting region 140a and the second light emitting region 140b, and a light emission mode in which only light emission is performed without showing a display using the difference in currents. It is therefore not necessary to design a configuration of elements for a display or to finely adjust the current to be applied.

As described above, according to the present exemplary embodiment, since a portion of the organic layer 120 (organic layer 120a) located in the first light emitting region 140a is heated, the peak intensity ratio of a light emission output spectrum in the first light emitting region 140a of the light emitting unit 140 is different from the peak intensity ratio of a light emission output spectrum in the second light emitting region 140b. Therefore, it is possible to make the light emission color in the first light emitting region 140a different from the light emission color in the second light emitting region 140b. In addition, since the amount of irradiated light on the organic layer 120a is small, the organic pigment of the organic layer 120a is not deteriorated. Therefore, it is possible to suppress a reduction in the life span of the light emitting device 10.

In addition, the irradiation of the organic layer 120a with light is performed after the light emitting unit 140 is sealed using the sealing portion 160, thus allowing the step of irradiating the organic layer 120a with light to be performed outside a vacuum device. Consequently, an increase in manufacturing costs of the light emitting device 10 can be suppressed.

### Modification Example 1

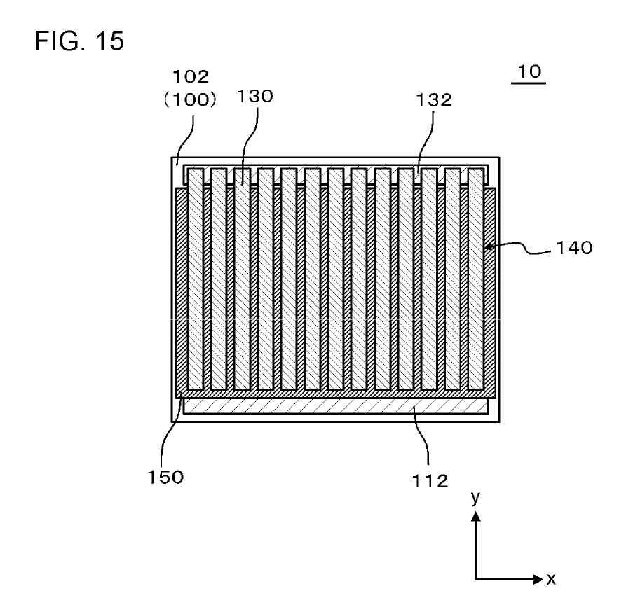

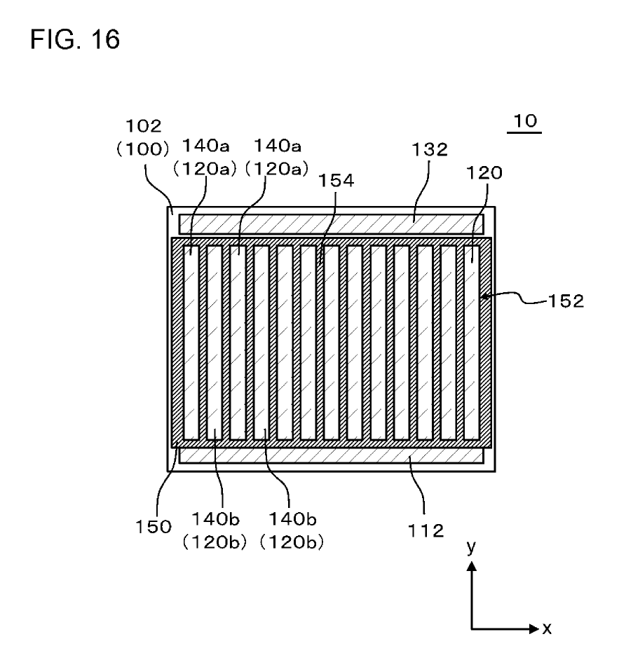

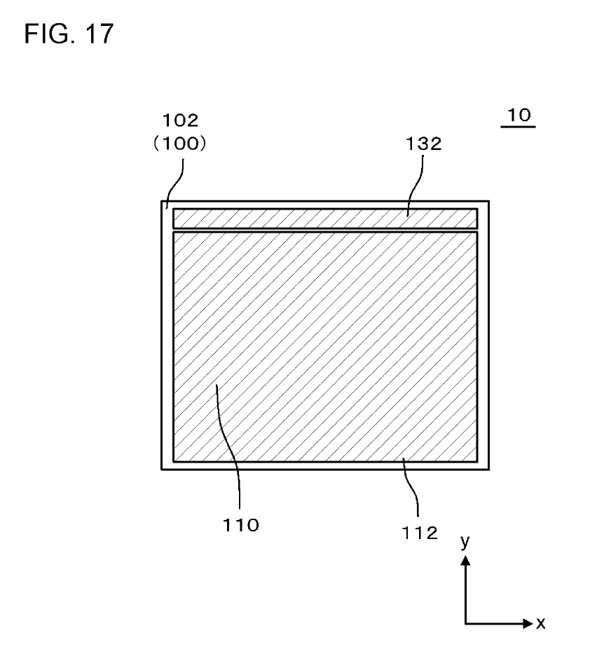

FIG. 15 is a plan view illustrating a configuration of the light emitting device 10 according to Modification Example 1, and corresponds to FIG. 1 in the exemplary embodiment. FIG. 16 is a diagram in which the second electrode 130 is removed from FIG. 15. FIG. 17 is a diagram in which the insulating layer 150 and the organic layer 120 are removed from FIG. 16. The light emitting device 10 according to the present modification example has the same configuration as that of the light emitting device 10 according to the exemplary embodiment except in the following respects.

First, the insulating layer 150 includes plural openings 152 in a region overlapping the first electrode 110. The organic layer 120 is located in each of the plural openings 152. In other words, the light emitting unit 140 is divided into plural light emitting regions. In the example illustrated in the drawing, the first light emitting regions 140a and the second light emitting regions 140b are alternately disposed. However, the arrangement of the first light emitting regions 140a and the second light emitting regions 140b is not limited to the example illustrated in the drawing.

Further, the second electrode 130 is individually provided for each of the first light emitting regions 140a and the second light emitting regions 140b. However, the plural second electrodes 130 may be connected to a common second terminal 132. In addition, the plural second electrodes 130 maybe connected to the respective second terminals 132. In this manner, it is possible to individually control currents to be applied to the plural second electrodes 130, that is, currents to be applied to the first light emitting regions 140a and currents to be applied to the second light emitting regions 140b. It is possible to adjust the light emission colors of the light emitting device 10 as a whole by individually controlling the currents to be applied. Such control is performed by a control unit 200 to be described later. In the present modification example, the second electrode 130 is formed using a mask, for example. Meanwhile, the second electrode 130 may be formed into a predetermined pattern by etching.

In addition, the insulating layer 150 located between the first light emitting regions 140a and the second light emitting regions 140b serves as a light limiting layer 154. The light limiting layer 154 is provided in order to prevent light incident on the second light emitting region 140b from being incident on the first light emitting region 140a due to reflection, scattering, or the like when the organic layer 120 of the second light emitting region 140b is irradiated with light. The light transmittance of the light limiting layer 154 in a near-infrared region or an infrared region may be, for example, equal to or less than 50%, and a difference in the transmittance of infrared rays between the light limiting layer 154 and another portion may be equal to or greater than 10%. In order to achieve the above, the light limiting layer 154 is formed by adding a low transmittance material having a light (for example, light in a near-infrared region or an infrared region) transmittance lower than that of a resin material constituting the light limiting layer 154. In this case, a low transmittance material is also added to a portion of the insulating layer 150 other than the light limiting layer 154. The low transmittance material is, for example, carbon, but may be another material.

Meanwhile, the light limiting layer 154 of the insulating layer 150 may be formed by a separate step from that of another portion of the insulating layer 150, whereby the low transmittance material can be added only to the light limiting layer 154.

In addition, the light limiting layer 154 may include particles or a layer that reflects light (for example, metal particles such as Al or a metal layer). In a case where the metal layer is provided, the resin material of the light limiting layer 154 covers the metal layer.

Also in the present modification example, it is possible to make the light emission color in the first light emitting region 140a different from the light emission color in the second light emitting region 140b, similarly to the exemplary embodiment. In addition, a reduction in the life span of the light emitting device 10 can be suppressed.

In addition, the light limiting layer 154 is formed between the first light emitting region 140a and the second light emitting region 140b. The light limiting layer 154 prevents light incident on the second light emitting region 140b from being incident on the first light emitting region 140a due to reflection, scattering, or the like when the organic layer 120 of the second light emitting region 140b is irradiated with light. Therefore, it is possible to clearly define a boundary between the first light emitting region 140a and the second light emitting region 140b and to prevent the width of the first light emitting region 140a from becoming larger than a design value.

### Modification Example 2

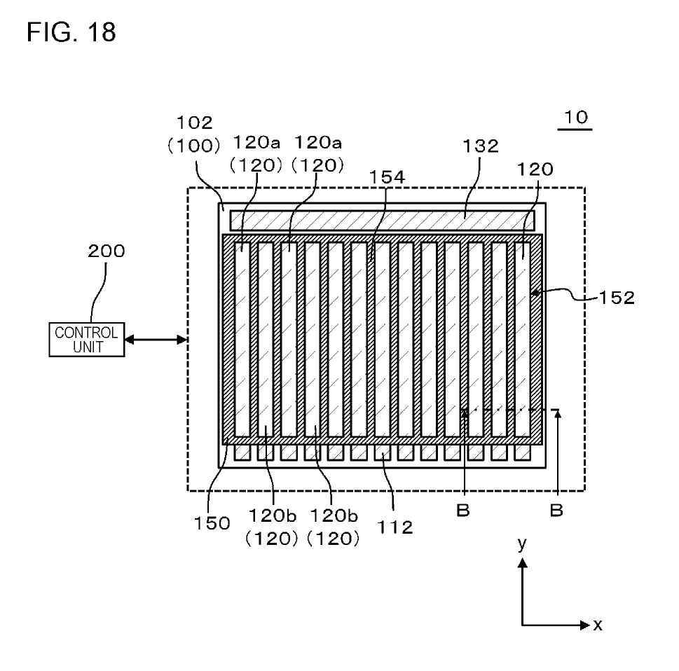

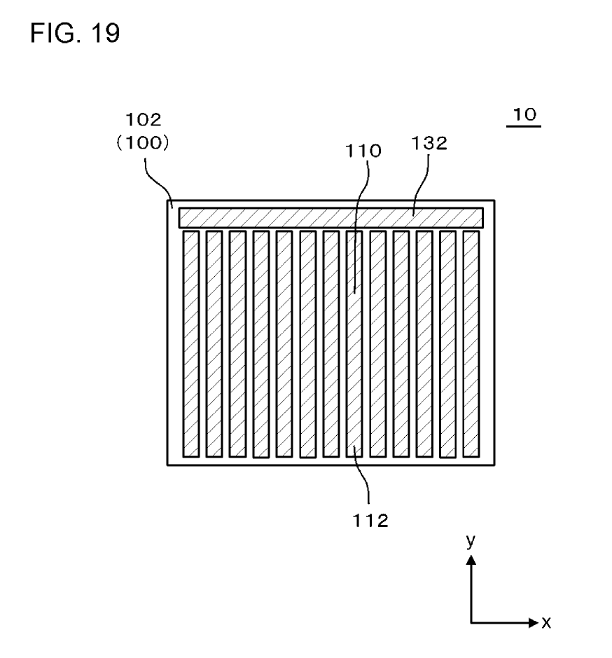

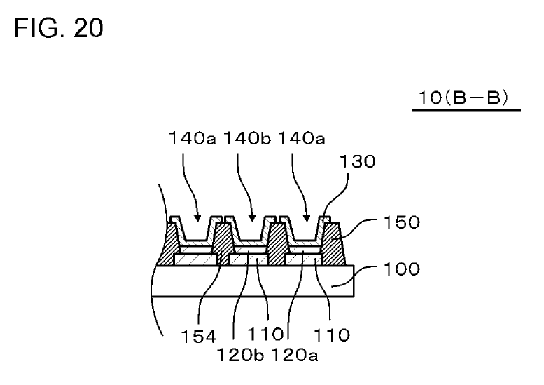

FIG. 18 is a plan view illustrating a configuration of the light emitting device 10 according to Modification Example 2, and corresponds to FIG. 16 in Modification Example 1. FIG. 19 is a diagram in which the insulating layer 150 and the organic layer 120 are removed from FIG. 18. FIG. 20 is a cross-sectional view taken along line B-B of FIG. 18. Meanwhile, in FIG. 20, the sealing portion 160 is not illustrated, and the second electrode 130 is illustrated for convenience of description.

The light emitting device 10 according to the present modification example has the same configuration as that of the light emitting device 10 according to Modification Example 1 except that the first electrode 110 is divided into plural parts. Specifically, a set of a first electrode 110 and a first terminal 112 is provided for each first light emitting region 140a, and a set of a first electrode 110 and a first terminal 112 is provided for each second light emitting region 140b. Therefore, the first electrode 110 of the first light emitting region 140a is separated from the first electrode 110 of the second light emitting region 140b. The light limiting layer 154 is located between adjacent first electrodes 110.

In the present example, methods of applying heat to the organic layer 120a of the first light emitting region 140a include applying a current only to the first light emitting region 140a to cause heat generation in the organic layer 120, in addition to irradiating the organic layer 120a with light. In the case of causing heat generation in the organic layer 120, it is not necessary to provide a light limiting layer 154, and instead, an insulating layer 150 not including a low transmittance material is provided between adjacent first and second light emitting region 140a and 140b.

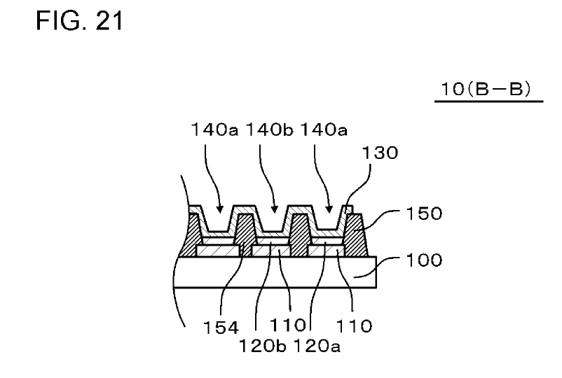

Meanwhile, in the present modification example, the second electrodes 130 may be connected to each other as illustrated in FIG. 21.

Also in the present modification example, it is possible to make the light emission color in the first light emitting region 140a different from the light emission color in the second light emitting region 140b, similarly to Modification Example 1. Further, a reduction in the life span of the light emitting device 10 can be suppressed. Still further, it is possible to clearly define a boundary between the first light emitting region 140a and the second light emitting region 140b and to prevent the width of the first light emitting region 140a from becoming larger than a design value.

In addition, the first electrode 110 is individually provided for each of the plural first light emitting regions 140a and the plural second light emitting regions 140b. Therefore, as illustrated in FIG. 18, the amount of current supplied to the first light emitting region 140a and the amount of current supplied to the second light emitting region 140b may be individually controlled by providing and using the control unit 200 for controlling the supplied current amount to the light emitting regions 140. In this case, the control unit 200 is capable of making the light emission color in the first light emitting region 140a and the light emission color in the second light emitting region 140b different from or the same as each other. In addition, the control unit 200 is capable of subtly changing the color of the light emitting unit 140. For example, it is possible to change the light emission color of the light emitting unit 140 to a blue-tinged white or a red-tinged color. The adjustment of the light emission color of the light emitting device 10 performed by the control unit 200 may not only be a two-stage adjustment but also a multi-stage adjustment.

### Modification Example 3

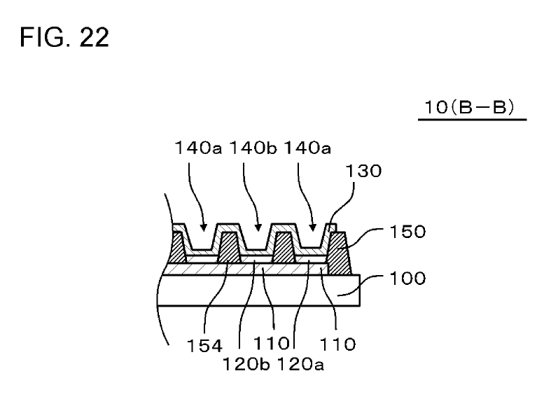

FIG. 22 is a cross-sectional view illustrating a configuration of the light emitting device 10 according to Modification Example 3, and corresponds to FIG. 20 in Modification Example 2. The light emitting device 10 according to the present modification example has the same configuration as that of the light emitting device 10 according to Modification Example 2 except that the first electrode 110 of the first light emitting region 140a and the first electrode 110 of the second light emitting region 140b adjacent the first light emitting region 140a are connected to each other and that the second electrode 130 of the first light emitting region 140a and the second electrode 130 of the second light emitting region 140b adjacent the first light emitting region 140a are connected to each other. In other words, the present modification example is the light emitting device 10 according to the exemplary embodiment but provided with the light limiting layer 154 according to Modification Example 1.

Also in the present modification example, it is possible to make the light emission color in the first light emitting region 140a different from the light emission color in the second light emitting region 140b. In addition, it is possible to suppress a reduction in the life span of the light emitting device 10. Further, it is possible to clearly define the boundary between the first light emitting region 140a and the second light emitting region 140b and to prevent the width of the first light emitting region 140a from becoming larger than a design value.

As described above, the exemplary embodiment and the examples have been described with reference to the accompanying drawings. However, these are just are illustrative of the invention, and various configurations other than the above-described configurations can also be adopted.

1. A light emitting device comprising:
a substrate; and
a light emitting unit on the substrate,
wherein the light emitting unit comprises a first light emitting region and a second light emitting region, and
wherein the first light emitting region and the second light emitting region are adjacent each other, each region comprising a first electrode, a second electrode, and an organic layer between the first electrode and the second electrode,
the light emitting device further comprising
a light limiting layer on the substrate between the first light emitting region and the second light emitting region, the light limiting layer preventing light incident on the second light emitting region from being incident on the first light emitting region.

2. A light emitting device comprising:
a substrate;
a first light emitting region and a second light emitting region on the substrate and are adjacent to each other; and
a light limiting layer on the substrate and between the first light emitting region and the second light emitting region,
wherein the light limiting layer comprises a low transmittance material having a light transmittance lower than a light transmittance of a material constituting the light limiting layer.

3. The light emitting device according to claim 2,
wherein the low transmittance material is carbon.

4. The light emitting device according to claim 1,
wherein each of a first light emission spectrum that is a light emission spectrum in the first light emitting region and a second light emission spectrum that is a light emission spectrum in the second light emitting region includes a first peak and a second peak, and an intensity ratio of the second peak with respect to the first peak of the first light emission spectrum is different from an intensity ratio of the second peak with respect to the first peak of the second light emission spectrum.

5. The light emitting device according to claim 4,
wherein the organic layer comprises a first light emitting layer and a second light emitting layer.

6. The light emitting device according to claim 5,
wherein a light emission spectrum of the first light emitting layer has the first peak, and
wherein a light emission spectrum of the second light emitting layer has the second peak.

7. The light emitting device according to claim 1,
wherein the first electrode in the first light emitting region is separated from the first electrode in the second light emitting region.

8. The light emitting device according to claim 7,
wherein the light limiting layer is between the first electrode in the first light emitting region and the first electrode in the second light emitting region.
